(19) United States
(12) Patent Application Publication
(10) Pub. No.: US 2025/0120204 A1
(43) Pub. Date: Apr. 10, 2025

(54) MULTI-CHIP IMAGE SENSOR SEMICONDUCTOR PACKAGE

(71) Applicant: UTAC Headquarters Pte. Ltd., Singapore (SG)

(72) Inventors: Jeffrey Punzalan, SINGAPORE (SG); IL KWON SHIM, SINGARORE (SG)

(21) Appl. No.: 18/981,677

(22) Filed: Dec. 16, 2024

Related U.S. Application Data
(63) Continuation-in-part of application No. 18/516,997, filed on Nov. 22, 2023.
(60) Provisional application No. 63/429,159, filed on Dec. 1, 2022.
(60) Provisional application No. 63/610,417, filed on Dec. 15, 2023.

(51) Int. Cl. H10F 39/00; H10F 39/95

(52) U.S. Cl. CPC H10F 39/804; H10F 39/011; H10F 39/811; H10F 39/95

(57) ABSTRACT

Multi-chip image sensor semiconductor packages and methods for forming such packages are disclosed. A multi-chip package includes at least one cover covering a sensor die. Some multi-chip packages include multiple covers for covering each sensor die. In one multi-chip packages, a single cover covers multiple sensor chips.

### CROSS-REFERENCE TO RELATED APPLICATION

This application is a continuation in part of U.S. application Ser. No. 18/516,997 filed on 22 Nov. 2023, which claims the benefit of U.S. Provisional Application No. 63/429,159 filed on 1 Dec. 2022. This application also claims the benefit of U.S. Provisional Application No. 63/610,417, filed on Dec. 15, 2023. The disclosures of above said references are all incorporated herein by reference for all purposes.

### FIELD OF THE INVENTION

The present disclosure relates to semiconductor packages for image sensors and the manufacturing methods of such packages. In particular, the present disclosure relates to multi-chip image sensor semiconductor packages. Multi-chip image sensor packages are particularly suitable for advanced light detection and ranging (LiDAR) applications, such as those used in automobile applications.

### BACKGROUND

Semiconductor packages are employed for packaging semiconductor chips. For example, in the case of sensor packages, they are employed for packaging sensor chips. A sensor chip includes a sensor for sensing non-electrical signals from the surrounding environment. The sensor chip converts the non-electrical signals received into electrical signals that are transmitted to a printed circuit board. For example, an image sensor chip converts incoming light into an electrical signal that can be viewed, analyzed, or stored. Image sensors may be used in electronic imaging devices of both analog and digital types, which include digital cameras, camera modules and medical imaging equipment. Commonly used image sensors may include semiconductor charge-coupled devices (CCD) or active pixel sensors formed using complementary metal-oxide-semiconductor (CMOS) or N-type metal-oxide-semiconductor (NMOS, Live MOS) technologies.

Typically, a sensor package includes wire bonds. Although the wire bonds are encased in an encapsulation, they can still be visible to the naked eye and can cause reflectance. This may impact the performance of the sensor chip and cause yield loss.

From the foregoing discussion, there is a desire to provide semiconductor packages with covers that can prevent the reflectance of visible wire bonds, thereby improving the performance of semiconductor sensor packages.

SUMMARY

Embodiments generally relate to semiconductor packages and methods for manufacturing thereof.

In one embodiment, a method of forming a multi-chip semiconductor package is disclosed. The method includes providing a package substrate with top and bottom major package substrate surfaces. The top package substrate surface includes at least first and second die regions with first and second die pads and a non-die region, The non-die region includes package bond pads. The bottom package substrate surface includes package contact pads. The package contact pads on the bottom package substrate surface are electrically connected to respective package bond pads on the top package substrate surface. The method also includes attaching a first die to the first die region. The first die includes a first sensor die having first active and inactive major die surfaces. The first active die surface includes a first sensor region with a sensor, a first non-sensor region with first die bond pads and a first cover adhesive region at least partially surrounding the first sensor region. The first inactive die surface is attached to the first die pad. The method also includes attaching a second die to the second die region. The second die includes second active and inactive major die surfaces. The second active die surface includes second die bond pads and the second inactive die surface is attached to the second die pad. The method also includes forming wire bonds connecting to the first and second die bond pads. The wire bonds at least connect the first die bond pads to the package bond pads to connect the first and second dies to the package substrate. The method also includes forming a first cover adhesive disposed on a first adhesive region. The method also includes attaching a first transparent cover having top and bottom first cover surfaces. The bottom first cover surface is disposed on the first adhesive. The first cover forms a first sealed cavity over the first sensor region. The method further includes encapsulating the package with an encapsulant. The encapsulant encapsulates exposed portions of the top package substrate surface, the first die, wire bonds and the second die while leaving the top first cover surface exposed.

In another embodiment, the present disclosure relates to a multi-chip semiconductor package. The package includes a package substrate with top and bottom major package substrate surfaces. The top package substrate surface includes at least first and second die regions with first and second die pads and a non-die region. The non-die region includes package bond pads. The bottom package substrate surface includes package contact pads. The package contact pads on the bottom package substrate surface are electrically connected to respective package bond pads on the top package substrate surface. The package also includes a first die disposed on the first die region. The first die includes a first sensor die having first active and inactive major die surfaces. The first active die surface includes a first sensor region with a sensor, a first non-sensor region with first die bond pads and a first cover adhesive region at least partially surrounding the first sensor region. The first inactive die surface is attached to the first die pad. The package also includes a second die disposed on the second die region. The second die includes second active and inactive major die surfaces. The second active die surface includes second die bond pads and the second inactive die surface is attached to the second die pad. The package also includes wire bonds connected to the first and second die bond pads. The wire bonds at least connect the first die bond pads to package bond pads to connect the first and second dies to the package substrate. The package also includes a first cover adhesive disposed on the first adhesive region. The package also includes a first transparent cover having top and bottom first cover surfaces. The bottom cover surface is disposed on the first adhesive. The first cover forms a first sealed cavity over the first sensor region. The package further includes an encapsulant. The encapsulant encapsulates exposed portions of the top package substrate surface, the first die, wire bonds and the second die while leaving the top first cover surface exposed.

These and other advantages and features of the embodiments herein disclosed will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of various embodiments. In the following description, various embodiments of the present disclosure are described with reference to the following, in which:

FIGS. 1a-1d show simplified cross-sectional views of embodiments of multi-chip image sensor semiconductor packages;

FIGS. 2a-2d show simplified cross-sectional views of other embodiments of

multi-chip image sensor semiconductor packages;

FIGS. 3a-3d show simplified cross-sectional views of yet other embodiments of multi-chip image sensor semiconductor packages;

FIGS. 4a-4f show simplified cross-section views of a process for forming an embodiment multi-chip image sensor semiconductor package;

FIGS. 5a-5b show simplified cross-section views of a process for forming another embodiment of a multi-chip image sensor semiconductor package;

FIGS. 6a-6c show simplified cross-section views of a process for forming yet another embodiment of a multi-chip image sensor semiconductor package;

FIGS. 7a-7b show simplified cross-section views of a process for forming

another embodiment of a multi-chip image sensor semiconductor package;

FIGS. 8a-8b₃ show simplified cross-section views of processes for forming other embodiments of multi-chip image sensor semiconductor packages;

FIGS. 9a-9e show simplified cross-section views of a process for forming another embodiment of a multi-chip image sensor semiconductor package; and

FIGS. 10a-10d show simplified top views of a package strip with multiple multi-chip image sensor.

### DETAILED DESCRIPTION

Embodiments described herein generally relate to semiconductor packages and methods for forming thereof. In particular, embodiments relate to multi-chip sensor packages. The multi-chip sensor packages may include a combination of sensor and non-sensor chips. In other embodiments, the multi-chip packages may include multiple sensor chips. The semiconductor package may be incorporated into electronic devices or equipment, such as sensing devices, navigation devices, telecommunication devices, computers and smart devices.

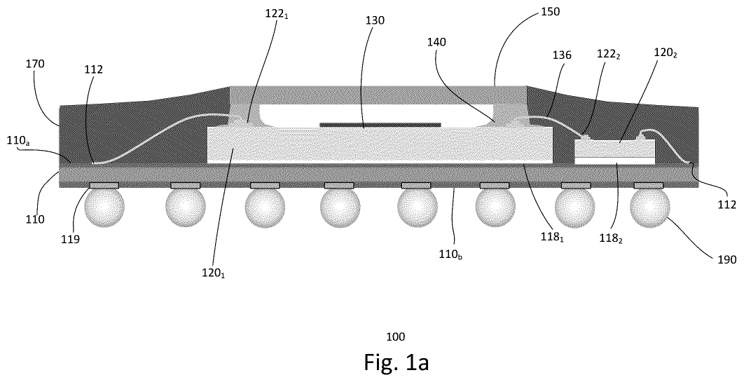

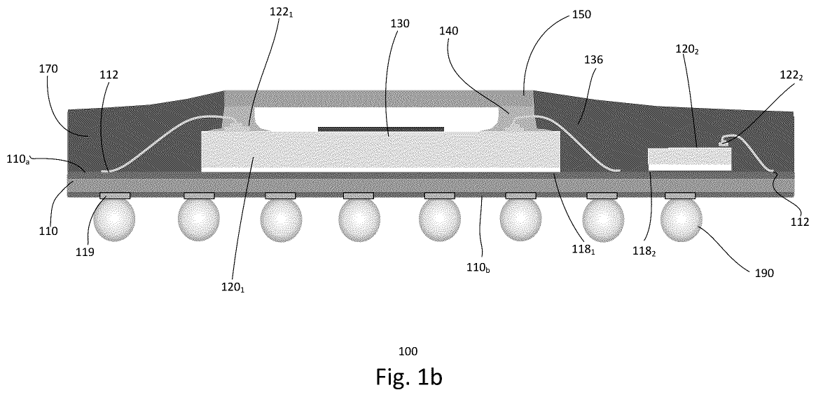

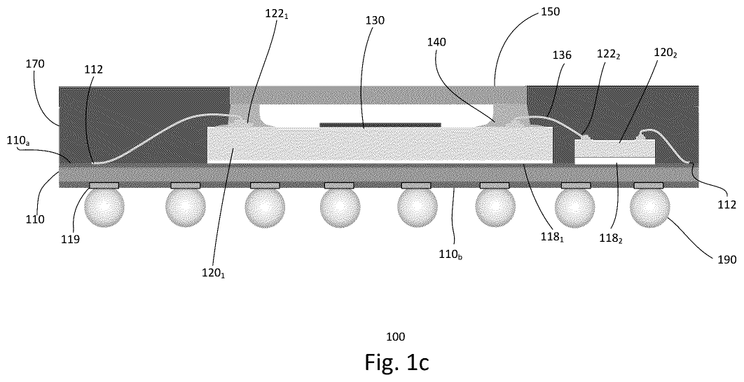

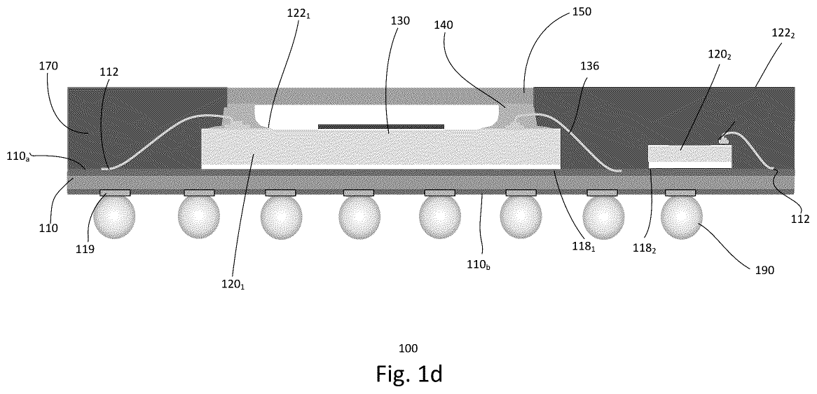

FIGS. 1a-1b show simplified cross-sectional views of embodiments of multi-chip sensor semiconductor packages. Referring to FIG. 1a, a semiconductor package 100 is shown. The semiconductor package 100 includes a package substrate 110 having opposing first and second major surfaces 110a and 110b. The first major surface 110a may be referred to as the top substrate surface and the second major surface 110b may be referred to as the bottom substrate surface. The top substrate surface serves as a bonding surface for dies 120. For example, the top substrate surface includes die pad regions on which dies are attached. In the case of a two-die multi-chip package, the top substrate surface includes first and second die pads for attaching first and second dies 120₁₋₂.

The die pads may be referred to as die regions of the top package substrate surface while non-die pad regions may be referred to as non-die regions. The non-die regions may surround the die regions. For example, the die regions may be disposed adjacently (side-by-side) within the top surface of the package substrate with the non-die regions surrounding them. Other configurations of the die and non-die regions may also be useful.

The package substrate may be a multi-layered substrate. For example, the package substrate includes a stack of electrically insulating substrate layers with interconnect lines therebetween. The different layers of the package substrate 110 may be laminated or built up. Via contacts are provided in the insulating layers to electrically connect interconnect lines of other layers. In one embodiment, the package substrate is a laminate-based substrate including a core or intermediate layer sandwiched between top and bottom substrate layers. Other types of substrates, including ceramic and leadframe substrates, may also be useful. It is understood that the package substrate may have various configurations, depending on design requirements.

The top surface of the package substrate may include package bond pads 112. The package bond pads are disposed in the non-die region of the top package substrate surface. The bottom package surface may include package contact pads 119 with package contacts 190 connected thereto. The package bond pads, for example, are electrically coupled to the package bond pads of the top surface of the package substrate. For example, each package pad is coupled to its respective package bond pad. The package substrate may include one or more conductive layers embedded therein. The conductive layers may form interconnect structures including conductive traces and via contacts for interconnecting the package contacts to package bond pads. The package contacts provide external connections to the package.

As shown, first and second dies 120₁₋₂ are attached to first and second die pads on the top package substrate surface. A die, for example, includes first and second opposing major die surfaces. The first major surface may be referred to as a top or active die surface and the second major surface may be referred to as a bottom or inactive die surface. The active die surface includes die bond pads. For example, the first die includes first die bond pads 122₁ on its active surface and the second die includes second die bond pads 122₂ on its active surface.

In one embodiment, the first die 120₁ is an image sensor chip. For example, the active or top die surface includes a sensor region with a sensor 130. The sensor region may be centrally disposed on the top die surface surrounded by a non-sensor region. Other configurations of the sensor and non-sensor regions may also be useful. The first die bond pads 122₁ are disposed within the non-sensor region.

As for the second die 120₂, it is a non-image sensor die. For example, the second die may be a logic chip, an application specific integrated circuit (ASIC) or a memory chip. Other types of non-image sensor chips may also be useful. Second die bond pads are disposed on the active die surface.

In one embodiment, the first die 120₁ is an image sensor chip. The image sensor chip, for example, includes an image sensor for detecting radiation or light. The image sensor, for example, is a CMOS image sensor. Other types of sensors may also be useful. In one embodiment, the sensor region includes an array of sensors. For example, each sensor may correspond to a pixel of an image. The sensor chip may include CMOS components embedded in the chip for controlling the sensor chip. Other configurations of the sensor chip may also be useful.

The dies are attached to the die pads of the package substrate by a die adhesive. For example, a first die adhesive 118₁ attaches the inactive surface of the first die to the first die pad; a second die adhesive 118₂ attaches the second die to the second die pad. The adhesives may be curable glue or adhesive tapes. For example, a curing process may be performed to permanently attach the dies to the die regions. Other types of die adhesives may also be useful to attach the die to the die regions. The bottom surface of the die, for example, is attached to the die region. For example, the inactive die surface is attached to the die region of the package substrate. The adhesive may be cured to permanently attach the die to the package substrate.

The active die surface may include die bond pads 122 disposed outside of the sensor region. For example, the die bond pads may be disposed on the non-sensor region of the active surface of the die. The die bond pads provide external electrical connections to various components of the chip. In one embodiment, wire bonds 136 are provided to couple the package bond pads to the die bond pads. The wire bonds, for example, are gold wire bonds. Other conductive wire bonds may also be useful. The wire bonds enable external connections to the internal circuitry of the die.

In one embodiment, as shown, bond wires couple the die bond pads of the dies to the package bond pads 112 of the package substrate as well as coupling die bond pads of the dies together. For example, first die bond pads 122₁ of the first die 120₁ are coupled to the package bond pads 112; second die bond pads 122₂ of the second die 120₂ are coupled to package bond pads; one or more first bond pads are coupled to one or more second die bond pads. Other configurations of connecting the dies to the package substrate may also be useful. The package contacts 190 provide external connections to the internal circuitry of the dies.

In one embodiment, a cover 150 is disposed on the first die over the sensor region. The cover includes first or top and second or bottom opposing major cover surfaces and side surfaces. In one embodiment, the cover is a rectangular-shaped cover with opposing top and bottom surfaces and four side surfaces. Other shaped covers may also be useful. The bottom cover surface, for example, faces the die. The cover is a transparent cover to enable light or radiation to penetrate through to the sensor region. For example, the cover may be a glass cover. Other types of transparent cover may also be useful. The cover thickness of the cover may be about 0.4-0.5 mm. Other thicknesses may also be useful.

A cover adhesive 140 may be employed to attach the cover 150 over the die. In one embodiment, the top die surface includes an adhesive region on which the cover adhesive is disposed. The adhesive region, for example, surrounds the sensor region. In one embodiment, as shown, the adhesive region is disposed on a periphery portion of the die active surface with a gap or space between the outer edge of the sensor region and the inner sides of the adhesive region. For example, an adhesive ring is disposed on the adhesive region surrounding the sensor region for attaching the cover 150 to the die. The adhesive may be a curable adhesive. For example, a curing process may be performed to permanently attach the cover to the die. In one embodiment, the curing process to attach the cover is separate from the curing process to attach the die. In one embodiment, the first die bond pads are disposed within the adhesive region. This reduces the footprint of the die, and as a result, the package. Providing the die bond pads outside of the adhesive region may also be useful. Other configurations of the adhesive region may also be useful. For example, the adhesive region should be configured to optimize the sensor area. In addition, the adhesive should be configured to prevent reflection and refraction of light. Other configurations of the adhesive may also be useful.

The cover sufficiently covers the sensor region. For example, the center portion of the bottom cover surface has a rectangular shape which is larger than the sensor region, ensuring that it sufficiently covers the sensor region. Providing a center portion of the bottom cover surface with other shapes may also be useful. The cover forms a cavity over the sensor region. For example, the cover seals the sensor region. The cavity may be a hermetically sealed cavity. Providing a non-hermetic cavity, such as a nearly hermetic cavity maya also be useful. Other configurations of the cavity may also be useful.

In one embodiment, the bottom surface of the cover includes a bonding region. The bonding region, for example, may be referred to as a cover bonding region. The bonding region is aligned with the adhesive region on the active surface of the die. For example, the bonding region is a continuous ring-shaped region which is aligned with the cover adhesive region. The adhesive bonds the cover to the active surface of the die.

An encapsulant or encapsulation 170 is disposed on the package substrate. The encapsulant 170 covers the package substrate, exposed portions of the dies, wire bonds and sides of the cover 150. The encapsulant leaves the top of the cover exposed. Regarding the second die, since there is no cover, the encapsulant covers it. The top of the encapsulant, as shown is sloped. Other configurations of the top encapsulant surface may also be useful. For example, the top encapsulant surface may be a planar surface. The encapsulant may be a mold compound, such as an epoxy mold compound (EMC). Other types of encapsulants may also be useful. In one embodiment, the encapsulant may be configured to be opaque to light. For example, the encapsulant may include carbon pigments to optically isolate or block light. Other types of additives to render the encapsulant opaque to light may also be useful.

The encapsulant may be formed by dispensing filler epoxy. For example, a top surface of the encapsulant is non-planar. As shown, the top surface of the encapsulate slopes downward from the cover to the edge of the package. Other techniques or configurations of the encapsulant may also be useful.

In FIG. 1b, the package is similar to the package of FIG. 1a. Common elements may not be described or described in detail. As shown, the difference of the package of FIG. 1b to FIG. 1a is that there are no connections by bond wires between the first and second dies 120₁₋₂.

FIGS. 1c-1d show simplified cross-sectional views of other embodiments of multi-chip sensor semiconductor packages. For example, the package of FIG. 1b is similar to the package of Fig. la and the package of FIG. 1d is similar to the package of FIG. 1c. Common elements may not be described or described in detail. The difference with the packages of FIGS. 1c-1d is that the encapsulant 170 has a top surface with is coplanar with the top cover surface. For example, the encapsulant is formed by film assist molding using epoxy molding compound. Film assist molding employs a mold chase. For example, epoxy molding compound is dispensed into the mold chase. The encapsulant may be formed by other techniques, such as injection molding and compression molding.

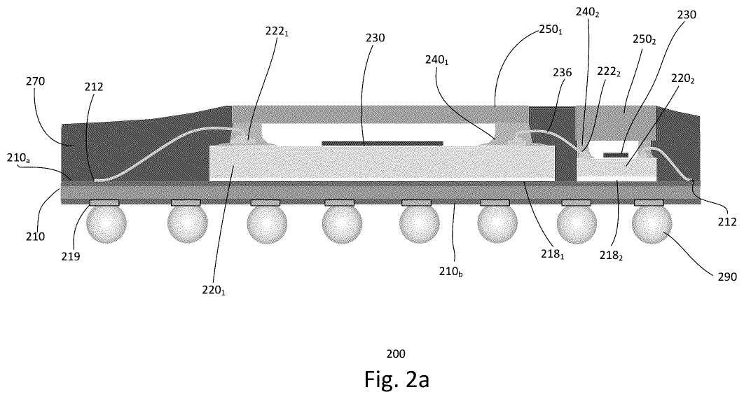

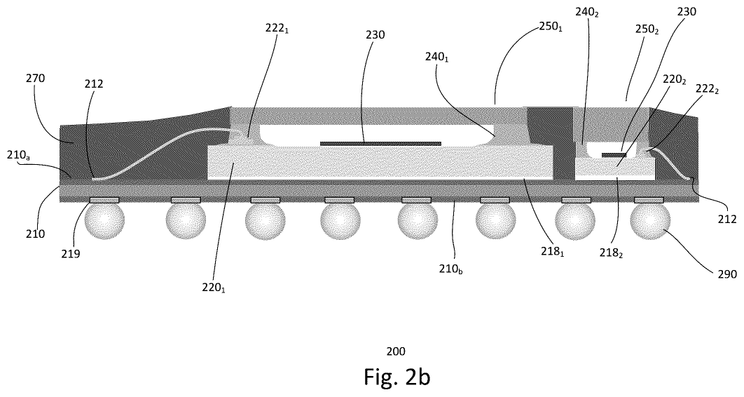

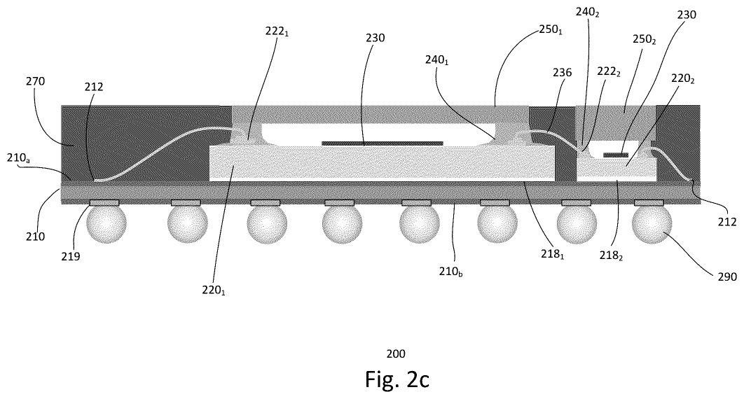

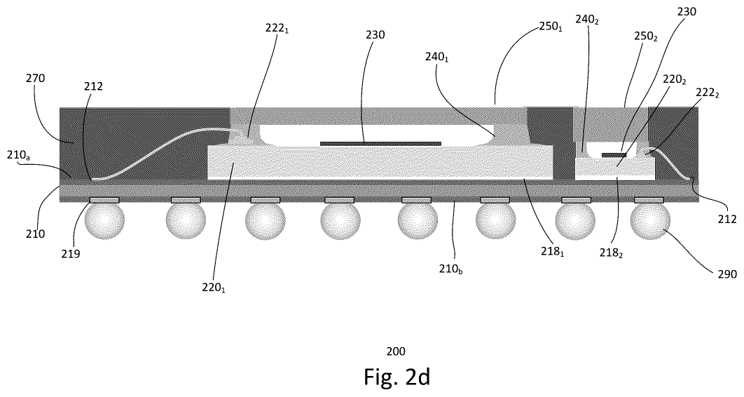

FIGS. 2a-2b show simplified cross-sectional views of other embodiments of multi-chip sensor semiconductor packages. For example, the package of FIG. 2a is similar to the package of Fig. la and the package of FIG. 2b is similar to the package of FIG. 1b. Common elements may not be described or described in detail. The difference with the packages of FIGS. 2a-2b is that they include first and second sensor dies 220₁₋₂ having image sensors 230 with separate first and second covers 250₁₋₂. In such cases, one sensor die, such as the first sensor die, may be employed for primary sensing while the other sensor die, such as the second sensor die, may be employed for secondary sensing (e.g., shadows and proximity lights). As shown, the sensor dies may be different types of sensor dies (different sizes) for different functionalities. Providing sensor dies having the same functionality may also be useful. Other configurations of sensor dies may also be useful. Also, as shown, the first die is thicker than the second die. In addition, the first cover is thinner than the second cover. This is to compensate for the differences in the die thicknesses so that the top surfaces of the first and second covers are coplanar. The dies may have the same thicknesses. In such cases, the covers may have the same thickness.

Similar to FIGS. 1a-1b, the top surface of the encapsulate slopes downward from the edges of the covers cover to the edge of the package. For example, the encapsulant may be formed by dispensing filler epoxy. Other techniques for forming the encapsulant may also be useful. In one embodiment, the encapsulant may be configured to be opaque to light. For example, the encapsulant may include carbon pigments to optically isolate or block light. This reduces or prevents light noise from interfering with the image sensor dies. Other types of additives to render the encapsulant opaque to light may also be useful.

FIGS. 2c-2d show simplified cross-sectional views of other embodiments of multi-chip sensor semiconductor packages. The packages of FIG. 2c-2d are similar to the packages of FIG. 2a-2b. Common elements may not be described or described in detail. The difference with the packages of FIGS. 2c-2d is that the encapsulant 270 have a planar top surface coplanar with top surfaces of the covers 250₁₋₂. Other configurations of the encapsulant may also be useful.

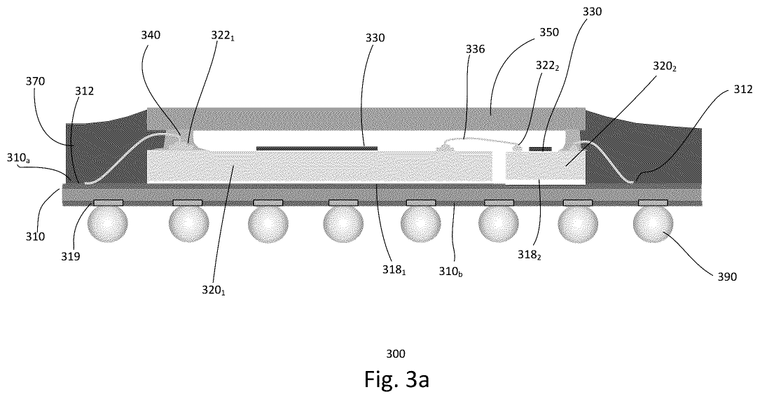

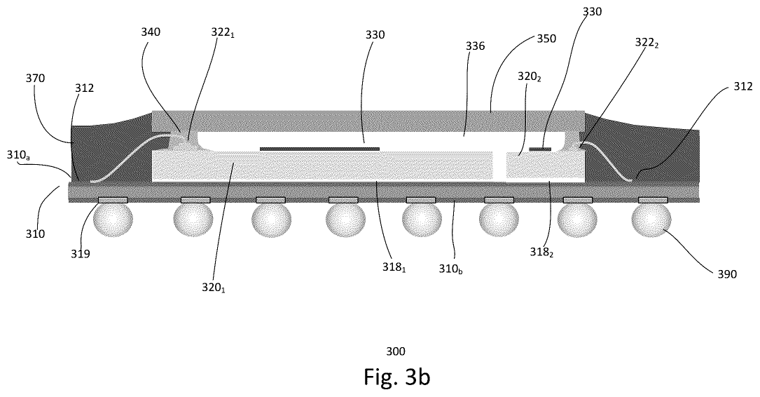

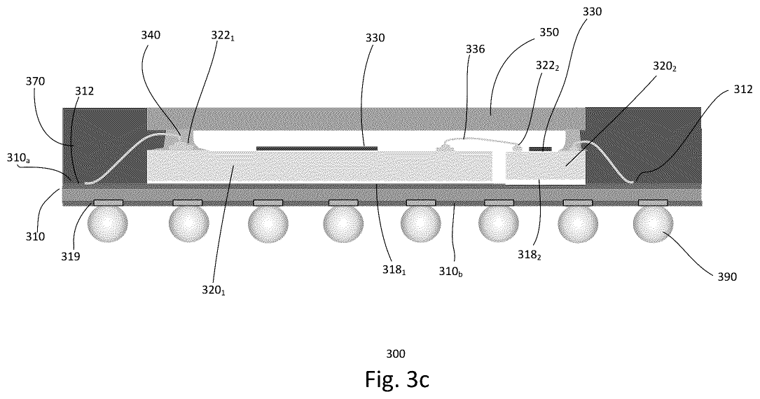

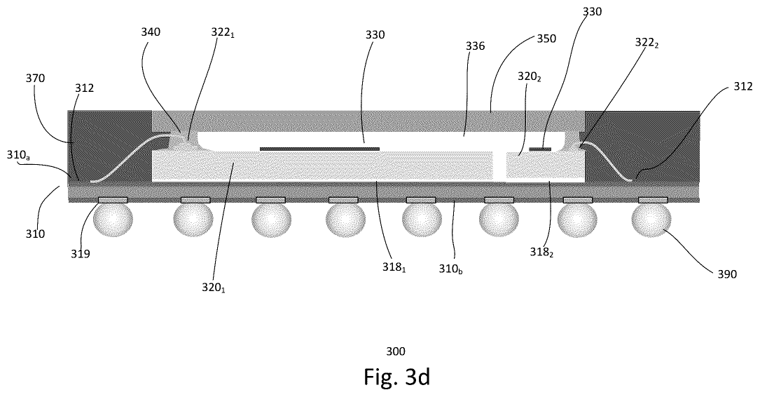

FIGS. 3a-3b show other embodiments of multi-chip semiconductor packages. The semiconductor packages of FIGS. 3a-3b are similar to those of FIGS. 2a-2b. Common elements may not be described or described in detail. As shown, the first and second dies 320₁₋₂ have the same thickness. Unlike FIGS. 2a-2b, a single cover 350 is employed to cover both dies. An adhesive 340 is employed to attach the cover to both dies. Since the thickness of the dies is the same, the height of the adhesive on both dies is also the same. In some embodiments, the thickness of the dies may not be the same. In such cases, the thickness of the adhesive on the different dies may be different to accommodate the difference in die thicknesses.

Similar to FIGS. 2a-2b, the encapsulant 370 top surface is non-planar. For example, the top surface of the encapsulant slopes downward from the cover to the edge of the package. The encapsulant may be formed by dispensing filler epoxy. For example, the encapsulant is a dispensed encapsulant. Other configurations of the encapsulant may also be useful. In one embodiment, the encapsulant may be configured to be opaque to light. For example, the encapsulant may include carbon pigments to optically isolate or block light.

FIGS. 3c-3d show other embodiments of multi-chip semiconductor packages. The semiconductor packages of FIGS. 3c-3d are similar to those of FIGS. 3a-3b. Common elements may not be described or described in detail. The encapsulant 370, as shown, has a planar to surface which is coplanar with top surface of the cover 350. The encapsulant may be formed by film assist molding. Forming the encapsulant by other molding processes, such as injection molding and compression molding, may also be useful. The encapsulant may also be configured to be opaque to light. Other configurations of the encapsulant may also be useful.

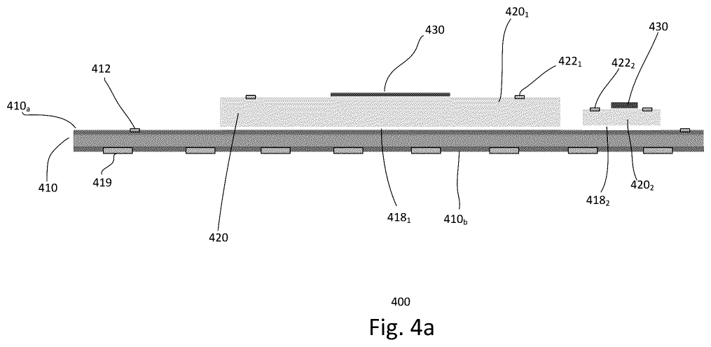

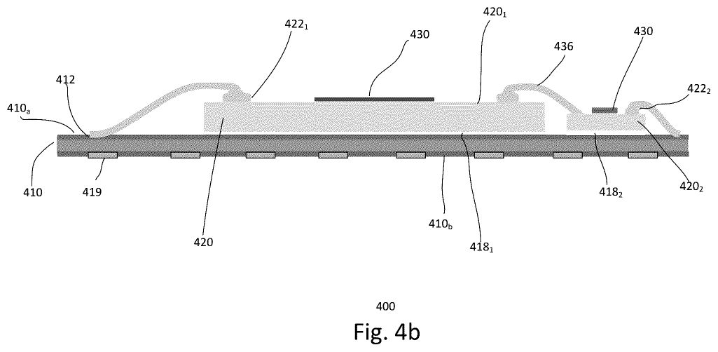

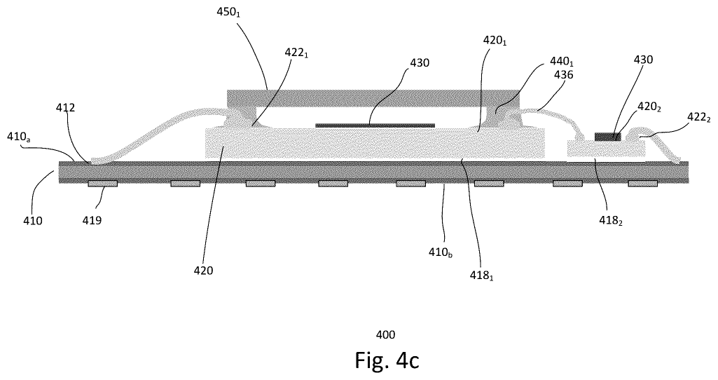

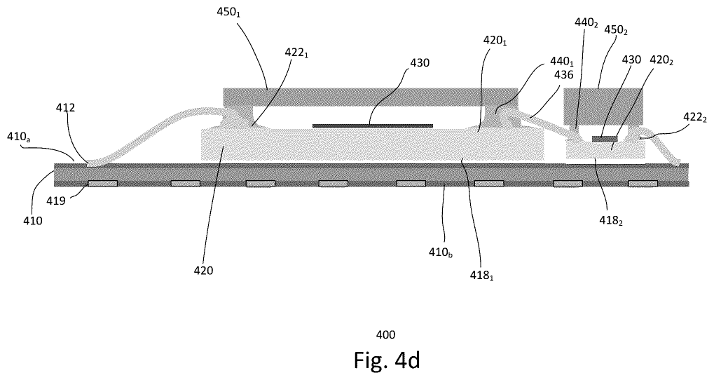

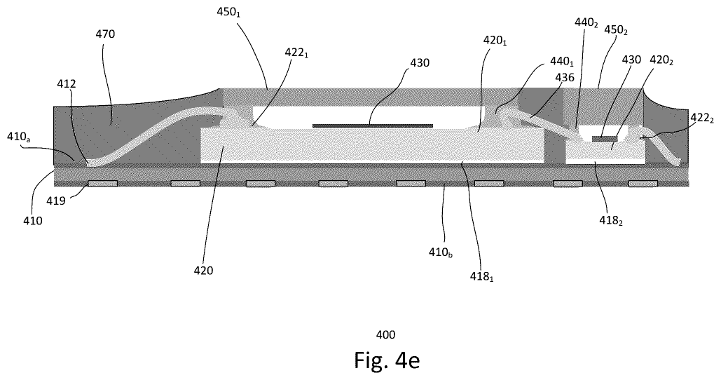

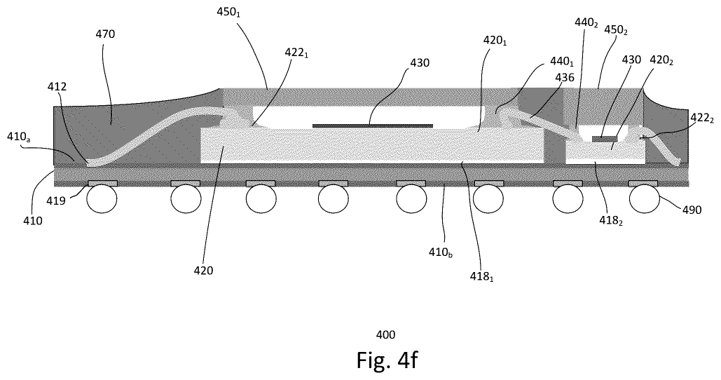

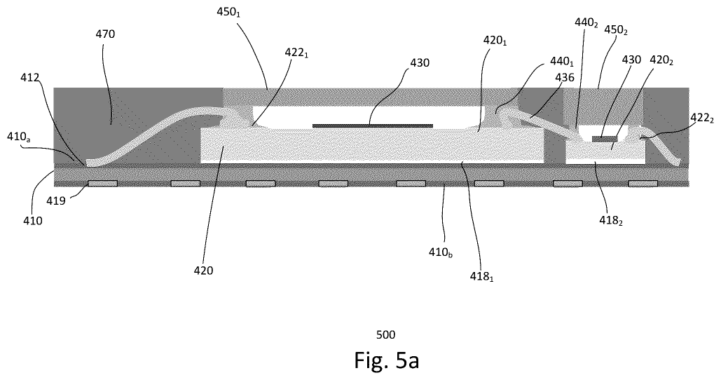

FIGS. 4a-4f shows a process 400 for forming an embodiment of a semiconductor package. The package is similar to those already described. Common elements may not be described or described in detail.

Referring to FIG. 4a, a package substrate 410 having opposing first (top) and second (bottom) major surfaces 410_{a-b} is provided. The package substrate may be a multi-layered substrate. The different layers of the package substrate may be laminated or built up. In one embodiment, the package substrate is a laminate-based substrate including a core or intermediate layer sandwiched between top and bottom substrate layers. Other types of substrates, including ceramic and leadframe substrates, may also be useful. It is understood that the package substrate may have various configurations, depending on design requirements.

The top package substrate surface includes die pads for attaching dies thereto. In one embodiment, the package substrate includes first and second die pads for attaching first and second dies 420₁₋₂. Providing more than 2 die pads may also be useful for attaching more than 2 dies to the package substrate. For example, x number of die pads are provided for attaching x number of dies to form an x multi-chip package, wherein x is greater than or equal to 2. The die pads form die regions of the top package substrate surface while a non-die region corresponds to the substrate surface outside of the die regions. The non-die region may be configured to surround the die regions. Other configurations of the die and non-die regions may also be useful.

The top package substrate surface also includes package bond pads 412. The package bond pads, in one embodiment, are disposed in the non-die region. As for the bottom package substrate surface, it may include package contact pads 419. The package pads on the bottom package substrate surface, for example, are electrically coupled to the package bond pads on the top surface of the package substrate. For example, each package pad is coupled to its respective package bond pad. The package substrate may include one or more conductive layers embedded therein. The conductive layers may form interconnect structures including conductive traces and via contacts for interconnecting the package pads on the bottom package surface to the package bond pads on the top package surface.

First and second dies or chips 420₁₋₂ are aligned and attached to the first and second die pads on the top package substrate surface. A die includes active and inactive major die surfaces. In one embodiment, the inactive die surface is attached to a die pad. The active surface includes die bond pads. For example, the first die includes first die bond pads 422₁; the second die includes second die bond pads 422₂. In one embodiment, the first and second dies are sensor dies. For example, a sensor is located in a sensor region of the active die surface of the first and second dies. The sensor region may be centrally disposed on the active die surface surrounded by a non-sensor region. Other configurations of the sensor and non-sensor regions may also be useful. Providing a second die which is not a sensor die may also be useful. As shown, the first die is thicker than the second die. Providing first and second dies having the same height may also be useful. Other configurations of dies may also be useful.

As discussed, the inactive die surface of the dies is attached to the die pads of the package substrate. For example, the inactive die surface of the first die is attached to a first die pad; the inactive die surface of the second die is attached to a second die pad. Attaching the dies may be achieved using, for example, first and second die adhesives 418₁₋₂. The die adhesives may be curable glue or adhesive tapes. For example, a curing process may be performed after attaching the dies to the die pads, permanently attaching the dies to the package substrate. Other types of die adhesives may also be useful to attach the dies to the die pads.

In FIG. 4b, wire bonding is performed. For example, wire bonds 436 connect first die bond pads 422₁ of the first die 420₁ to package bond pads 412, wire bonds connect second die bond pads 422₂ of the second die 420₂ to package bond pads, and wire bonds connect first die bond pads of the first die to second die bond pads of the second die. Other wire bond configurations for connecting the dies to the package substrate may also be useful.

As shown in FIG. 4c, a first sealing process is performed for sealing the first sensor region of the first die. In one embodiment, the sealing process includes dispensing a first cover adhesive 440₁ on a first cover adhesive region on the active die surface of the first die surrounding the sensor region. For example, an adhesive dispenser is configured to dispense the first cover adhesive on the first cover adhesive region. The first cover adhesive region is disposed on the non-sensor region of the first active die surface surrounding the sensor region. In one embodiment, as shown, the first cover adhesive region includes the first die bond pads 422₁. Other configurations of the first cover adhesive region may also be useful. For example, the adhesive region should be configured to optimize the sensor area.

The first cover adhesive has sufficient viscosity to enable it to form a continuous adhesive ring on the first cover adhesive region having a desired height. The desired height may be about 100 to 150 um. Other heights may also be useful, depending on the requirements. The desired height should be able to accommodate the looped wire bonds without damaging them. The cover adhesive may also be configured to prevent reflection and refraction of light.

A first cover 450₁ is aligned to the package and attached to the first cover adhesive. This forms a cavity over the die, sealing the sensor region. The cover is a transparent cover to enable light or radiation to penetrate through to the sensor in the sensor region. For example, the cover may be a glass cover. Other types of transparent cover may also be useful. The cover thickness of the cover may be about 0.4-0.5 mm. Other thicknesses may also be useful.

Referring to FIG. 4d, a second sealing process is performed. The second sealing process is similar to first sealing process except that it seals the second sensor region of the second die 422₂. For example, a second adhesive 440₂ is disposed in a second cover adhesive region. As shown, the second cover adhesive region includes the second die bond pads 422₂. In one embodiment, the height of the second adhesive is about the same as the first adhesive of the first die.

A second cover 450₂ is attached to the second adhesive sealing the second sensor region of the second die. In one embodiment, the second cover is thicker than the first cover. For example, the thickness of the second cover is about the same as the thickness of the first die. This results in the top surfaces of the first and second covers to be coplanar.

After attaching the covers, a curing process may be performed. The curing process permanently attaches the covers to the dies. The cover structures form cavities over the sensor regions. For example, the first cover forms a first cavity over the first sensor region of the first die, the second cover forms a second cavity over the second sensor region of the second die. In one embodiment, the cavities may be vacuum or hermetic cavities. Forming non-hermetically sealed cavities may also be useful. For example, the cavities may be nearly hermetic.

In FIG. 4e, the process continues to encapsulate the package. For example, an encapsulant 470 is formed to encapsulate the package. The encapsulant may be a mold compound, such as an epoxy mold compound (EMC). Other types of encapsulants may also be useful. The encapsulant may be formed by dispensing filler epoxy. The encapsulant covers the package substrate, exposed portions of the die, wire bonds and sides of the covers. The encapsulant leaves the top of the covers exposed. As shown, the epoxy has a non-planar top surface. For example, the epoxy slopes downward from the edge of the covers to toward the edge of the package substrate. The space or gap between the dies, as shown, is planar. Other techniques for forming the encapsulant may also be useful.

Referring to FIG. 4f, the process continues to form package contacts 490 on package contact pads 419 on the bottom package surface. The package contacts, for example, may be solder balls. In one embodiment, a ball mount process is employed to form the package contacts. Other types of package contacts or processes of forming package contacts may also be useful.

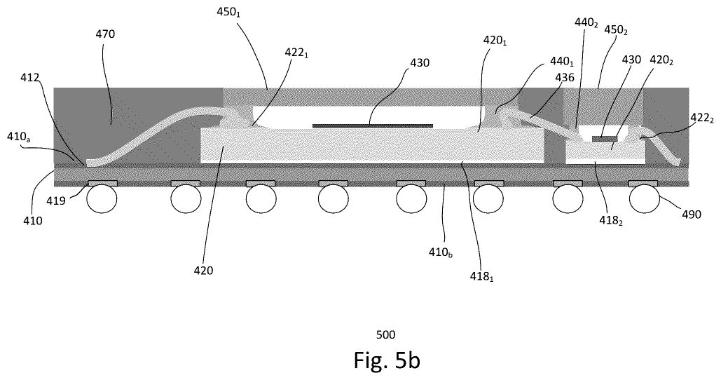

FIGS. 5a-5b show a process 500 for forming another embodiment of a package. The package and process are similar to the package and process of FIGS. 4a-4f. Common elements may not be described or described in detail.

As shown in FIG. 5a, the process is at the stage of processing as FIG. 4e. The difference is that the encapsulant 470 has a planar top surface. For example, the encapsulant is formed by film assist molding. Other techniques for forming the encapsulant may also be useful. The process continues, as shown in FIG. 5b, to form package contacts 490 on package contact pads 419 on the bottom package surface.

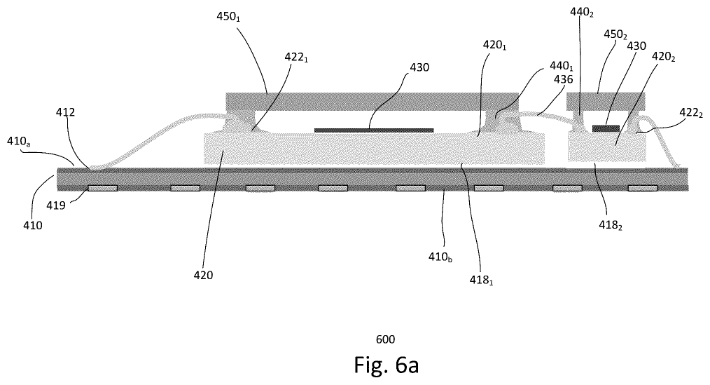

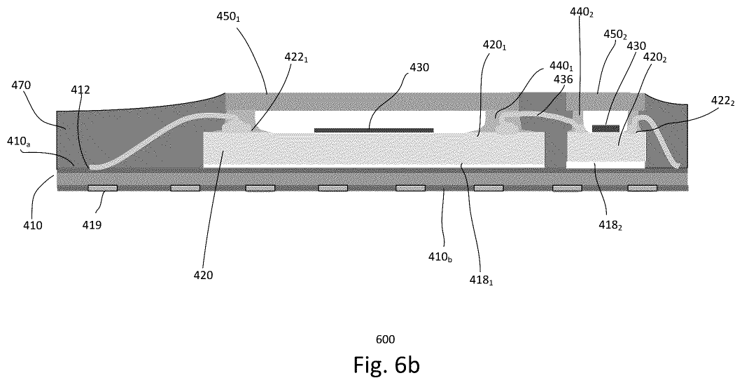

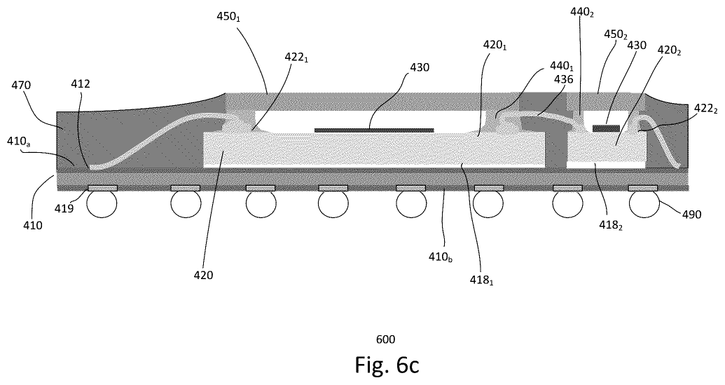

FIGS. 6a-6c show a process 600 for forming yet another embodiment of a package. The package and process are similar to the package and process of FIGS. 4a-4f. Common elements may not be described or described in detail.

Referring to FIG. 6a, the stage of processing is similar to that of FIG. 4d. For example, first and second sealing processes are performed to seal the first and second sensor dies. Unlike FIGS. 4a-4f, the first and second dies 420₁₋₂ have the same thickness. In one embodiment, the first and second covers and adhesives also have the same height or thickness.

In FIG. 6b, an encapsulant 470 is formed to encapsulate the package. The encapsulant may be formed by dispensing filler epoxy. The encapsulant has a non-planar top surface. For example, the epoxy slopes downward from the edge of the covers to toward the edge of the package substrate. The space or gap between the dies, as shown, is planar. Other techniques for forming the encapsulant may also be useful. After forming the encapsulant, package contacts 490 are formed on package contact pads 419, as shown in FIG. 6c.

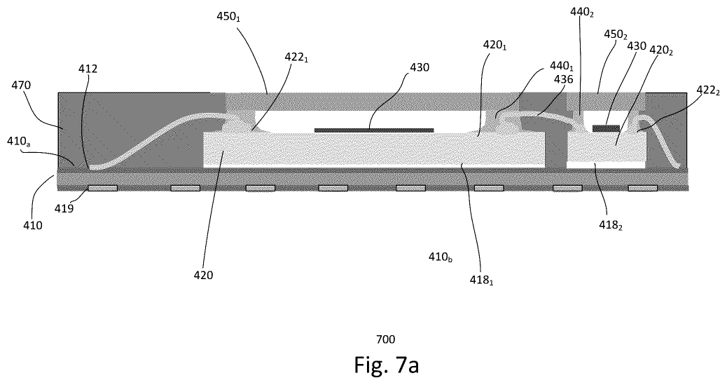

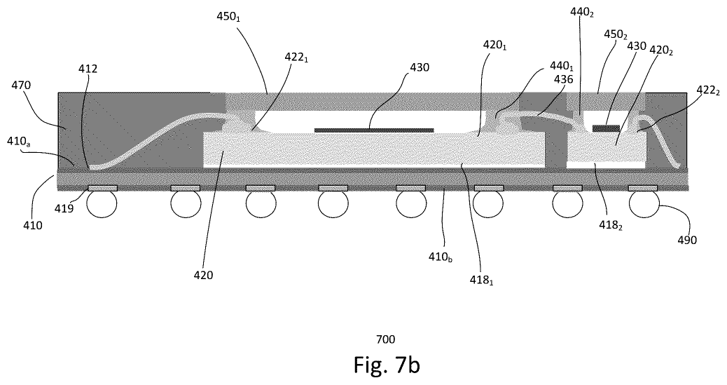

FIGS. 7a-7b show a process 700 for forming another embodiment of a package. The package and process are similar to the package and process of FIGS. 6a-6b. Common elements may not be described or described in detail.

As shown in FIG. 7a, the process is at the stage of processing as FIG. 6b. The difference is that the encapsulant 470 has a planar top surface. For example, the encapsulant is formed by film assist molding. Other processes for forming the encapsulant may also be useful. The top encapsulant surface, in one embodiment, is coplanar with the top surfaces of the covers. The process continues, as shown in FIG. 7b, to form package contacts 490 on package contact pads 419 on the bottom package surface.

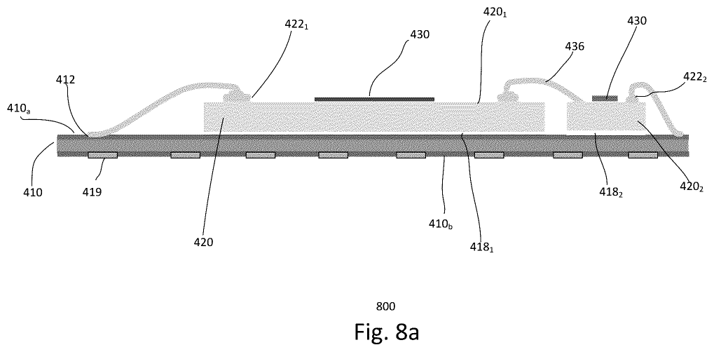

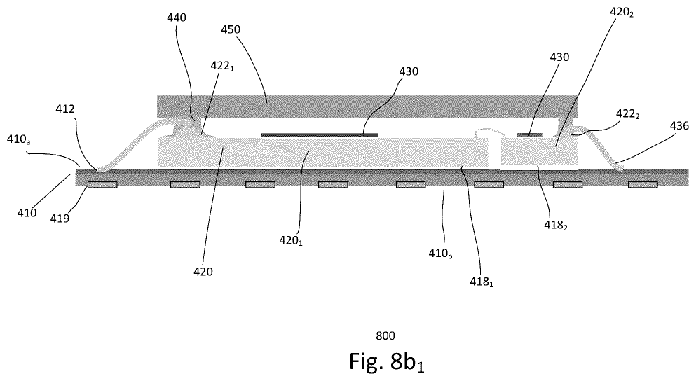

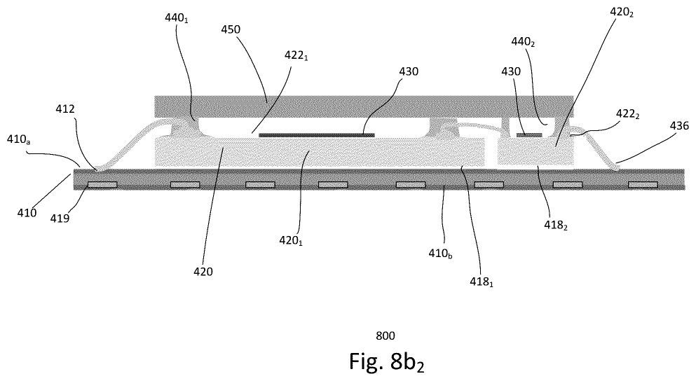

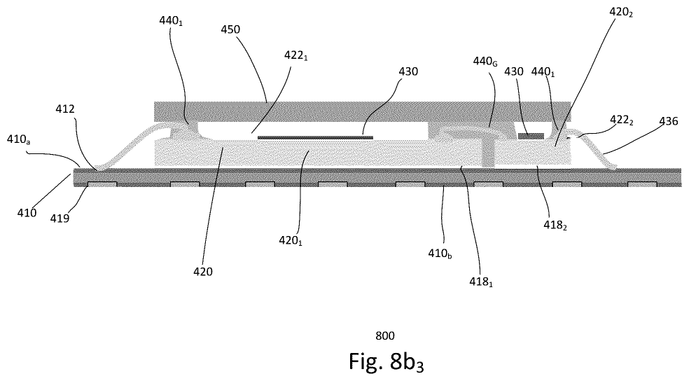

FIGS. 8a-8b₁₋₃ show a process 800 for forming another embodiment of a package. The package and process are similar to the packages and processes of FIGS. 4a-4f, 6a-6b and 7a-7b. Common elements may not be described or described in detail.

FIG. 8a shows a partially processed package at the stage of processing as FIG. 4b. For example, first and second dies sensor dies 420₁₋₂ are attached to die pads of the package substrate 410 by first and second die adhesives 418₁₋₂. As shown, wire bonds 436 connect the die bond pads 422₁₋₂ of the dies to the package bond pads 412 as well as to the die bond pads of the dies. Other configurations of connecting the dies by bond wires to the package substrate may also be useful. As shown, the thickness of the dies is the same.

Referring to FIG. 8b₁, an embodiment of a sealing process is performed. The sealing process includes dispensing a cover adhesive 440 on first and second cover adhesive regions on the active die surfaces of the first and second dies. In one embodiment, the cover adhesive regions do not completely surround the sensor regions. Instead, the sides of the dies which are adjacent do not include the cover adhesive regions. The package substrate between the gaps of the dies includes cover adhesive regions. For example, an adhesive dispenser is configured to dispense the cover adhesive on the cover adhesive region. A cover 450 is attached to the cover adhesive, forming a cavity over the first and second sensor regions of the first and second dies 420₁₋₂. For example, a single cavity is formed over the sensor regions of the dies.

In another embodiment, as shown in FIG. 8b₂, the sealing process forms first and second adhesive rings 440₁₋₂ are disposed on the periphery of the first and second dies, surrounding the sensor regions. A cover 450 is attached to the first and second adhesive rings, forming first and second cavities over the sensor regions of the first and second dies.

FIG. 8_{b3} shows yet another embodiment of a sealing process. The sealing process, similar to FIG. 8_{b2}, forms first and second adhesive rings 440₁₋₂ on the active surface of the first and second dies, surrounding the sensor regions. Unlike FIG. 8_{b2}, the sealing process also includes forming an adhesive which fills the gaps between the first and second dies. Like FIG. 8_{b2}, the sealing process forms 2 separate cavities over the sensor regions of the dies.

After the sealing process, the process continues to cure the cover adhesive to permanently attach the cover to the dies. After curing, package contacts are formed as already described.

As described in FIGS. 8a-8b, the dies of the package substrate are of the same height. Providing dies having different heights may also be useful. The sealing process will be performed so that the adhesive heights over the first and second dies may be different to compensate for the difference in die heights.

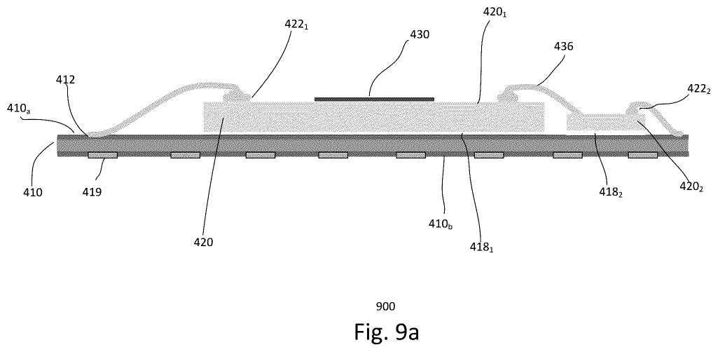

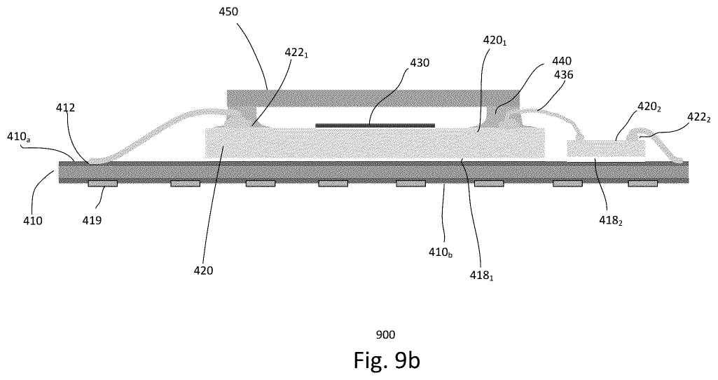

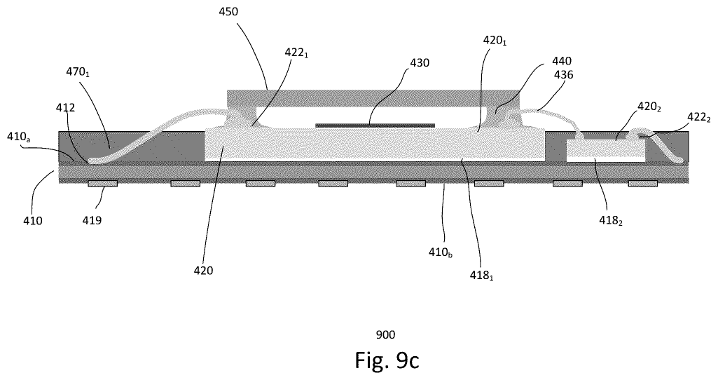

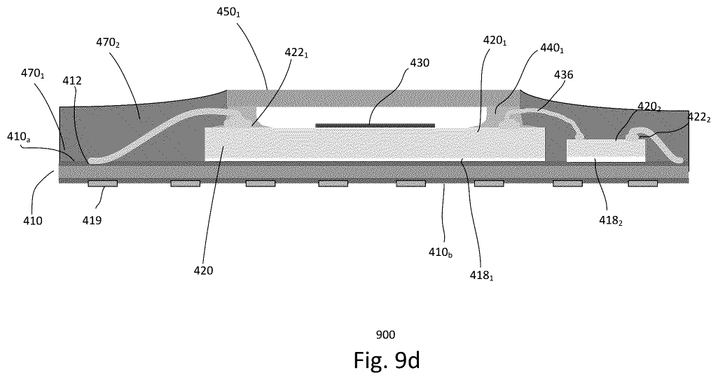

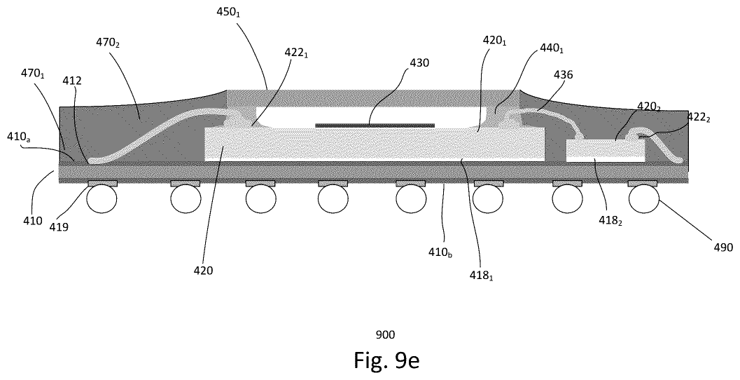

FIGS. 9a-9e shows a process 900 for forming another embodiment of a multi-chip package. The package and process is similar to those of FIGS. 4a-4f. Common elements may not be described or described in detail.

Referring to FIG. 9a, a partially processed package is shown. The process is at a similar stage as shown in FIG. 4b. For example, first and second dies 420₁₋₂ are attached to die pads on the top package substrate surface 410a of the package substrate 410 by first and second die adhesives 418₁₋₂. Wire bonds 436 connect die bond pads 422₁₋₂ of the dies to each other as well as to package bond pads 412. Other configurations of connecting the dies to the package substrate may also be useful. The difference is that the process is adjusted to accommodate forming a multi-chip package with one image sensor chip and one non-sensor chip. For example, the first die 420₁ is a sensor die and the second die 420₂ is a non-sensor die. The dies, as shown, have different heights. Other configurations of the dies of the multi-chip packages may also be useful.

As shown in FIG. 9b, a sealing process is performed. In one embodiment, the sealing process includes dispensing a cover adhesive 440 on the active die surface of the first die 420₁. The cover adhesive, for example, surrounds the sensor region with the sensor 430. A cover 450 is aligned to the first die and disposed on the cover adhesive. The cover forms a cavity over the sensor. After the cover is disposed on the cover adhesive, a curing process is performed. The curing process cures the adhesive, permanently attaching the cover to the first die.

Referring to FIG. 9c, an encapsulating process is performed. In one embodiment, the encapsulating process includes a first encapsulant process for forming a first encapsulant 470₁ on the package substrate. The first encapsulant partially encapsulates the package. As shown, the first encapsulant is formed to a level at or about the height of the first die 420₁. Partially forming the encapsulant to other heights may also be useful. A multi-step encapsulating process may be employed to improve encapsulation quality and maintain wire bond integrity. The first encapsulant may be formed by a dispensing process, partially filling the package substrate 410 with the first epoxy. The first encapsulant is partially cured. The first encapsulant may be cured at a temperature range of about 40-60° C. for about 4-6 seconds.

In FIG. 9d, a second encapsulating process is performed. The second encapsulating process forms a second encapsulant 470₂ over the first encapsulate to complete the encapsulating process. As shown, the second encapsulant is dispensed on the package over the first encapsulant. The top surface of the second encapsulant has a non-planar surface. For example, the second encapsulant slopes downward from the cover downward to the edge of the package substrate. The second encapsulant covers the second die 420₂. A curing process is performed after the encapsulating process. After the curing process, as shown in FIG. 9e, package contacts 490 are formed on the package contact pads 419.

As described, a multi-step encapsulating process is performed. In other embodiments, a single encapsulating process may be employed to fully encapsulate the package. Also as described, the encapsulating process includes a dispensing process to form a non-planar top encapsulant surface. In other embodiments, film assist molding may be employed to form an encapsulant with a planar top surface. Other processes for forming the encapsulant may also be useful.

Furthermore, the processes as described in FIGS. 4a-4f, 5a5b, 6a-6c, 7a-7b, 8a-8b and 9a-9e can be adjusted to form a plurality of packages in parallel. For example, a plurality of packages can be formed in parallel on a package strip having a plurality of unsingulated package substrates. The process can be similar to the processes described. For example, 1) a package strip with a plurality of unsingulated package substrates is provided, 2) attaching at least first and second dies to the package substrates of the package strip, 3) wire bonding to connect the dies to the package substrates with wire bonds (wire bonds may connect dies tighter), 4) performing one or more sealing processes to form one or more cavities over the dies, 5) performing an encapsulation process to encapsulate the packages, and 6) performing a singulation process to separate the package strip to form individual packages. The singulation process may include sawing the package strip. Other types of singulation processes may also be useful.

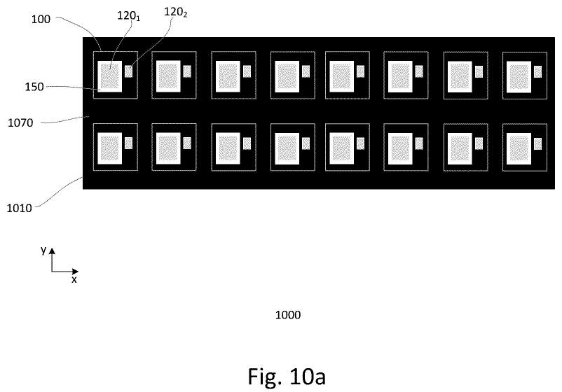

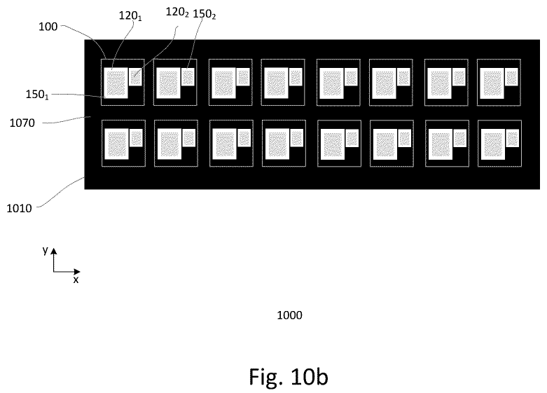

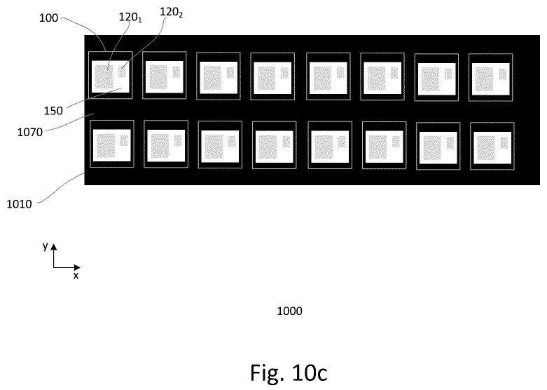

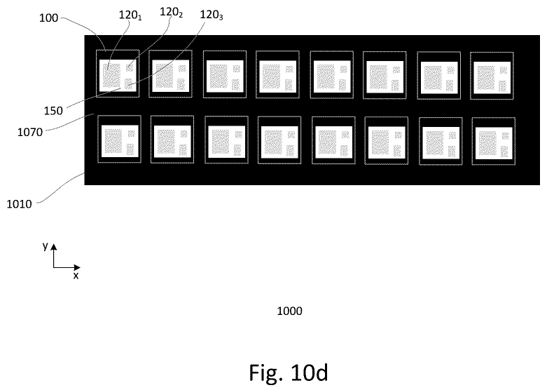

FIGS. 10a-10d show simplified top views of various embodiments of a processed package strip 1000 with unsingulated packages 100. The unsingulated packages of the package strip are similar to those already described in FIGS. 1a-1d, 2a-2d, and 3a-3d. Common elements may not be described or described in detail.

Referring to FIGS. 10a-10c, a package strip is configured with a matrix of unsingulated packages 100. The packages of the package strip may be configured in a matrix arrangement. For example, the packages are arranged in a 2×8 matrix. Other arrangements for the packages of the package strip may also be useful. A package of the package strip includes at least first and second dies 120₁₋₂, as shown in FIGS. 10a-10c. Providing more than 2 dies for a package may also be useful. For example, a package may be provided with first, second and third dies 120₁₋₃, as shown in FIG. 10d.

A package includes at least one cover 150. For example, as shown in FIG. 10a, the first die 120₁ is a sensor die while the second die 120₂ is a non-sensor die. The cover covers the first die while encapsulant 1070 covers the second die. In other embodiments, as shown in FIG. 10b, the first and second dies 120₁₋₂ of a package are sensor dies. The first and second covers 150₁₋₂ covers the first and second dies of the package. In yet other embodiments, a single cover covers the dies of a package, as shown in FIGS. 10a and 10d. Other configurations of covers for the packages of the package strips may also be useful.

The various embodiments of packages and methods for forming the packages may include providing or forming an opaque coating on the encapsulant, as described in U.S. application Ser. No. 18/516,997 filed on 22 Nov. 2023, titled “Semiconductor Packaging For Image Sensors”, which is already herein incorporated by reference for all purposes.

The inventive concept of the present disclosure may be embodied in other specific forms without departing from the spirit or essential characteristics thereof. The foregoing embodiments, therefore, are to be considered in all respects illustrative rather than limiting the invention described herein. The scope of the invention is thus indicated by the appended claims, rather than by the foregoing description, and all changes that come within the meaning and range of equivalency of the claims are intended to be embraced therein.

What is claimed is:

1. A method of forming a multi-chip semiconductor package comprising:
providing a package substrate with top and bottom major package substrate surfaces, wherein
the top package substrate surface includes at least first and second die regions with first and second die pads and a non-die region, the non-die region includes package bond pads, and
the bottom package substrate surface includes package contact pads, wherein the package contact pads on the bottom package substrate surface are electrically connected to respective package bond pads on the top package substrate surface;
attaching a first die to the first die region, wherein the first die comprises a first sensor die having first active and inactive major die surfaces, wherein
the first active die surface includes a first sensor region with a sensor, a first non-sensor region with first die bond pads and a first cover adhesive region at least partially surrounding the first sensor region, and
the first inactive die surface is attached to the first die pad;
attaching a second die to the second die region, wherein the second die comprises second active and inactive major die surfaces, wherein
the second active die surface includes second die bond pads, and
the second inactive die surface is attached to the second die pad;
forming wire bonds connecting to the first and second die bond pads, wherein the wire bonds at least connect the first die bond pads to the package bond pads to connect the first and second dies to the package substrate;
forming a first cover adhesive disposed on a first adhesive region;
attaching a first transparent cover having top and bottom first cover surfaces, the bottom first cover surface is disposed on the first adhesive, wherein the first cover forms a first sealed cavity over the first sensor region; and
encapsulating the package with an encapsulant, the encapsulant encapsulates exposed portions of the top package substrate surface, the first die, wire bonds and the second die while leaving the top first cover surface exposed.

2. The method of claim 1 wherein:
the first die comprises the first sensor die;
the second die comprises a second non-sensor die;
a first cover region with the first cover adhesive completely surrounds the first sensor region; and
the first transparent cover is disposed over the first cover adhesive to form the first sealed cavity over the first sensor region.

3. The method of claim 2 wherein the encapsulant covers the second die.

4. The method of claim 1 wherein:
the first die comprises the first sensor die; and
the second die comprises a second sensor die.

5. The method of claim 4 wherein
the first adhesive region with the first cover adhesive completely surrounds the first sensor region of the first sensor die; and
the second sensor die includes a second adhesive region which completely surrounds a second sensor region with a second sensor.

6. The method of claim 5 comprises:
forming a second cover adhesive on the second cover adhesive region;
providing a second cover having top and bottom second cover surfaces;
attaching the bottom second cover surface to the second cover adhesive, wherein the second cover forms a second sealed cavity over the second sensor region of the second die; and
wherein the encapsulant encapsulates exposed portions of the top package substrate surface, the first die, wire bonds and the second die while leaving the top first and second cover surfaces exposed.

7. The method of claim 5 wherein
the bottom first cover surface attaches to the first and second cover adhesives to form first and second cavities over the first and second sensor regions of the first and second sensor dies; and
the encapsulant encapsulates exposed portions of the top package substrate surface, the first die, wire bonds and the second die while leaving the top first cover surface over the first and second sensor dies exposed.

8. The method of claim 7 wherein the first and second cover adhesives fill a gap between the first and second sensor dies.

9. The method of claim 1 wherein
the first adhesive region with the first cover adhesive partially surrounds the first sensor region of the first sensor die except for adjacent sides of the first and second sensor dies; and
the second sensor die includes a second adhesive region which partially surrounds a second sensor region with a second sensor except for the adjacent sides of the first and second sensor dies.

10. The method of claim 9 comprises:
forming a second cover adhesive on the second cover adhesive region, wherein the first and second cover adhesive fills a gap between the first and second sensor dies to form a contiguous cover adhesive ring on the first and second sensor dies; and
wherein
the bottom first cover surface is attached to the adhesive ring and forms a common cavity with the first and second sensor regions of the first and second sensor dies, and
the bottom first cover surface attaches to the cover adhesive ring to form a common cavity over the first and second sensor regions;
the encapsulant encapsulates exposed portions of the top package substrate surface, the first die, wire bonds and the second die while leaving the top first cover surface exposed.

11. The method of claim 4 wherein:
the first and second dies comprise different die heights;
the first and second adhesives comprise different adhesive heights to compensate for the difference in die heights to result in top first and second cover surfaces to be about coplanar.

12. The method of claim 4 wherein:
the first and second dies comprise different die heights;
the first and second covers comprise different cover thicknesses to compensate for the difference in die heights to result in top first and second cover surfaces to be about coplanar.

13. The method of claim 1 wherein forming wire bonds comprises:
forming wire bonds connecting the first die bond pads of the first die to the second die bond pads to the second die;
forming wire bonds connecting the first die bond pads to the package bond pads; and
forming wire bonds connecting the second die bond pads to the package bond pads.

14. The method of claim 1 wherein forming wire bonds comprises:
forming wire bonds connecting the first die bond pads to the package bond pads; and
forming wire bonds connecting the second die bond pads to the package bond pads.

15. A multi-chip semiconductor package comprising:
a package substrate with top and bottom major package substrate surfaces, wherein
the top package substrate surface includes at least first and second die regions with first and second die pads and a non-die region, the non-die region includes package bond pads, and
the bottom package substrate surface includes package contact pads, wherein the package contact pads on the bottom package substrate surface are electrically connected to respective package bond pads on the top package substrate surface;
a first die disposed on the first die region, wherein the first die comprises a first sensor die having first active and inactive major die surfaces, wherein
the first active die surface includes a first sensor region with a sensor, a first non-sensor region with first die bond pads and a first cover adhesive region at least partially surrounding the first sensor region, and
the first inactive die surface is attached to the first die pad;
a second die disposed on the second die region, wherein the second die comprises second active and inactive major die surfaces, wherein
the second active die surface includes second die bond pads, and
the second inactive die surface is attached to the second die pad;
wire bonds connected to the first and second die bond pads, wherein the wire bonds at least connect the first die bond pads to package bond pads to connect the first and second dies to the package substrate;
a first cover adhesive disposed on the first adhesive region;
a first transparent cover having top and bottom first cover surfaces, the bottom cover surface is disposed on the first adhesive, wherein the first cover forms a first sealed cavity over the first sensor region; and
an encapsulant, the encapsulant encapsulates exposed portions of the top package substrate surface, the first die, wire bonds and the second die while leaving the top first cover surface exposed.

16. The device of claim 15 wherein:
the first die comprises a first sensor die;
the second die comprises a second non-sensor die;
the first cover region with the first cover adhesive completely surrounds the first sensor region; and
the first transparent cover is disposed over the first cover adhesive to form the first sealed cavity over the first sensor region.

17. The device of claim 16 wherein the encapsulant covers the second die.

18. The device of claim 15 wherein:
the first die comprises the first sensor die; and
the second die comprises a second sensor die.

19. The device of claim 18 wherein:
the second die comprises a second cover adhesive on a second adhesive region at least partially surrounding a second sensor region of the second sensor die; and
wherein the first bottom cover surface attaches to the first and second adhesive to form a common cavity over the first and second sensor regions of the first and second dies.

20. The device of claim 18 wherein:
the second die comprises a second cover adhesive on a second adhesive region at least partially surrounding a second sensor region of the second sensor die; and
wherein the first bottom cover surface attaches to the first and second adhesive to form first and second cavities over the first and second sensor regions of the first and second dies.
